(19) United States
(12) Patent Application Publication
(10) Pub. No.: US 2007/0164777 A1
(43) Pub. Date: Jul. 19, 2007

(54) SCAN CELL FOR AN INTEGRATED CIRCUIT

(75) Inventors: Chetan Verma, Noida (IN); Gulshan K. Miglani, Delhi (IN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/617,763

(22) Filed: Dec. 29, 2006

(30) Foreign Application Priority Data
Jan. 3, 2006 (IN) 29/DEL/2006

(51) Int. Cl. H03K 19/003

(52) U.S. Cl. 326/12

(57) ABSTRACT

A scan cell and a method for detecting supply voltage degradation in an integrated circuit using the scan cell. The scan cell includes a voltage comparator and a scan flip-flop. The voltage comparator compares a supply voltage with a reference voltage to generate a comparator output signal. The scan flip-flop is coupled to the voltage comparator, and receives the comparator output signal. Use of the scan cell for detecting IR drop replaces expensive methods like FIB (Focused Ion Beam) and EBEAM (electron beam).

### BACKGROUND OF THE INVENTION

The present invention relates generally to the field of integrated circuits (ICs) and in particular, to supply voltage degradation in ICs.

With a reduction in the size of the ICs as well as reduced device geometries, IR-drop or supply-voltage degradation has become an important factor that affects the performance of ICs. Currents in an IC increase due to the presence of more devices in a particular design and many currents passing through each device. In devices with small geometries, for example, in deep submicron technologies, there is a reduction in a supply voltage to the IC and an increase in parasitic effects due to the number and diameter of the wires, contacts and vias of the IC. The IR-drop can result in chip failure due to factors such as not meeting performance requirements, setup or hold time violations, or small noise margins. Further, the IR drop varies at different positions within the IC due to, for example, varying resistance of a power grid of the IC. This variation in IR drop can depend on several factors, such as current and resistance levels, placement of logic blocks within the IC, and interaction of the logic blocks that may result in the parasitic effects.

Several design solutions are available for checking and verifying the IR drop variation at the pre-silicon design stage. However, in spite of passing the traditional verification checks, the ICs can still fail at silicon due the complex nature of the designs.

Some of the techniques used for diagnosing IR drops at the post-silicon stage include the electron beam (EBEAM) and focused-ion beam (FIB) techniques. However, these techniques are expensive and also result in delays in the design cycle. Further, ICs that fail these diagnostic tests need to be redesigned, which results in a substantial loss of time and additional costs.

### BRIEF DESCRIPTION OF THE DRAWINGS

The following detailed description of preferred embodiments of the present invention will be better understood when read in conjunction with the appended drawings. The present invention is illustrated by way of example and not limited by the accompanying figures, in which like references indicate similar elements.

FIG. 1 is a schematic diagram of an integrated circuit (IC) in accordance with an exemplary embodiment of the present invention;

FIG. 2 is a schematic diagram of a scan cell in accordance with an exemplary embodiment of the present invention; and

FIG. 3 is a flowchart depicting a method for detecting supply voltage degradation in an integrated circuit in accordance with an exemplary embodiment of the present invention.

### DETAILED DESCRIPTION OF THE PRESENT INVENTION

The following detailed description in connection with the appended drawings is intended as a description of the presently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

The present invention provides a scan cell for detecting supply voltage degradation in an integrated circuit (IC). The IC includes a power grid. The power grid includes a plurality of power rails. The plurality of power rails carry a supply voltage within the IC. The scan cell includes a voltage comparator and a scan flip-flop. The voltage comparator compares the supply voltage carried by a selected one of the power rails with a reference voltage to generate a comparator output signal. The reference voltage is based on a predetermined threshold voltage drop in the IC. The scan flip-flop is coupled to the voltage comparator and receives the comparator output signal.

In another embodiment of the present invention, an integrated circuit (IC) including one or more scan cells and a power grid is provided. Each scan cell of the one or more scan cells detects supply voltage degradation in the IC. The power grid includes a plurality of power rails. The power rails carry a supply voltage within the IC. Each scan cell includes a voltage comparator and a scan flip-flop. The voltage comparator compares the supply voltage carried by a selected power rail from amongst the plurality of power rails with a reference voltage to generate a comparator output signal. The reference voltage is based on a predetermined threshold voltage drop in the IC. The scan flip-flop is coupled to the voltage comparator and receives the comparator output signal.

In yet another embodiment of the present invention, the present invention provides a method for detecting supply voltage degradation in an integrated circuit (IC). The IC includes a power grid having a plurality of power rails. The power rails carry a supply voltage within the IC. The method includes comparing the supply voltage carried by at least one of the power rails from amongst the plurality of power rails with a reference voltage to generate a comparator output signal. The reference voltage is based on a predetermined threshold voltage drop in the integrated circuit. The comparator output signal is provided to a scannable latch circuit.

The scan cell of the present invention detects supply voltage degradation in deep submicron chips at the post-silicon stage. The scan cell requires minimal logic to implement without affecting die size, and is cost-effective. Further, the scan cell does not require additional bonding pads, and can be implemented using the existing bonding pads by input/output multiplexing.

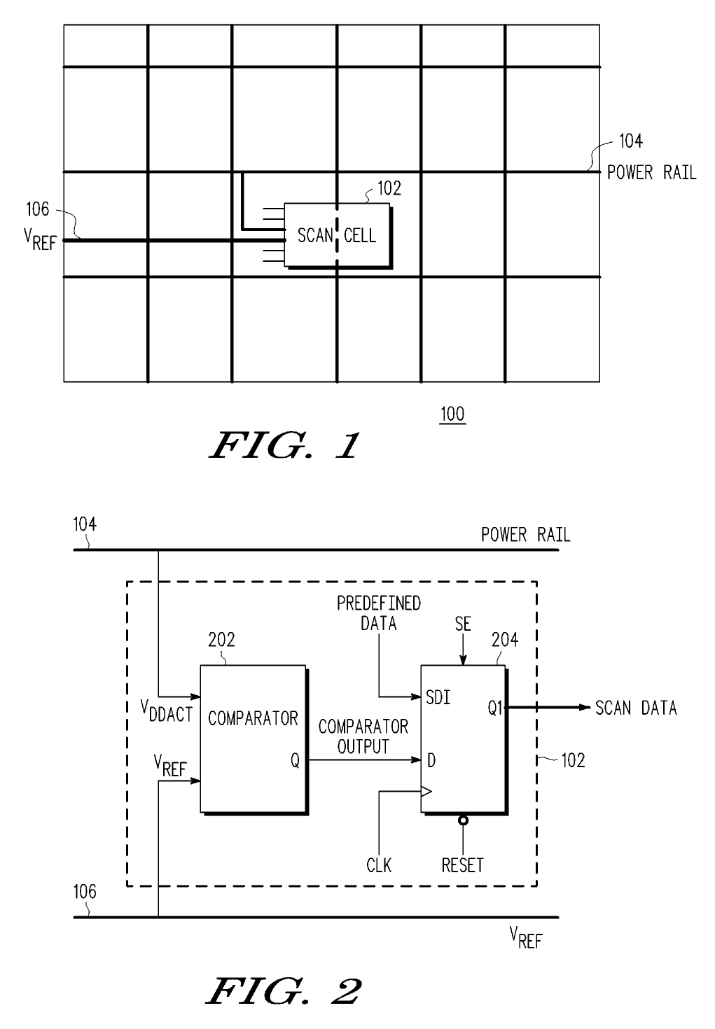

Referring now to FIG. 1, a schematic block diagram of an integrated circuit (IC) 100, in accordance with an embodiment of the present invention is shown. The IC 100 includes a power grid and one or more scan cells, for example, a scan cell 102. The power grid includes multiple power rails. The power rails, for example, a power rail 104, carry a supply voltage within the IC 100. A standalone power line 106 carries a reference voltage from a voltage source to the scan cell 102. The power line 106 is not connected to the power grid. Therefore, the reference voltage does not suffer from any degradation caused by any internal components of the IC 100. In one embodiment of the invention, the power line 106 carries the reference voltage directly from a bonding pad of the IC 100 to the scan cell 102. The value of the reference voltage depends on a predetermined threshold drop in the IC 100. In an embodiment of the present invention, the predetermined threshold drop is a maximum allowed voltage drop in the supply voltage for proper operation of the IC 100. The reference voltage can be represented as:
V_{REF}=V_{DD}−V_{IR}
where V_{IR} is the maximum allowed voltage drop, and V_{DD} is the supply voltage without degradation.

The scan cell 102 can be placed at suitable locations within the IC 100. The supply voltage V_{DD} is carried to the scan cell 102 at a suitable location by one of the selected power rails, for example, the power rail 104. The power rail is selected depending on the voltage drop of the power rail. For example, the power rail that is expected to suffer the maximum voltage drop is selected. In an embodiment of the present invention, the scan cell 102 is located proximate, close to, or at a point where the power rail 104 experiences near maximum supply voltage degradation. For example, the scan cell 102 can be located near to the center of the IC 100 where the power rail 104 experiences about maximum supply voltage degradation. At this point, the supply voltage is represented herein as V_{DDACT}.

FIG. 2 is a schematic diagram of the scan cell 102 in accordance with an exemplary embodiment of the present invention. The scan cell 102 includes a voltage comparator 202 and a scan flip-flop 204. The scan flip-flop 204 is a scannable latch circuit, which, for example, includes a D flip-flop. The voltage comparator 202 compares V_{DDACT} with V_{REF} and generates a comparator output signal in response to comparison of V_{DDACT} with V_{REF}. If V_{DDACT} is greater than V_{REF}, the comparator output signal is a ‘HIGH’ or ‘1’. However, if V_{DDACT} is less than V_{REF}, the comparator output signal is a ‘LOW’ or ‘0’. A HIGH comparator output signal indicates that the voltage or IR drop is within the predetermined threshold or is less than the maximum allowed voltage drop or supply voltage degradation. A LOW comparator output signal indicates that the IR drop has crossed the predetermined threshold or is greater than the maximum allowed supply voltage degradation. The scan flip-flop 204 is coupled to the voltage comparator 202. The comparator output signal is received by the scan flip-flop 204.

The scan flip-flop 204 has inputs D, SDI, and scan enable (SE), and an output Q1. The scan flip-flop 204 receives the comparator output signal at the D input and scan data such as from a scan chain at the SDI input. The scan flip-flop 204 is synchronized with a clock CLK. Further, a ‘RESET’ signal can set or reset the scan flip-flop 204 depending on a bit value of the RESET signal. When CLK is set, depending on a value of SE, the scan flip-flop 204 performs different functions. For example, when SE is active, the scan flip-flop 204 latches the comparator output signal. However, when SE is not active, the scan flip-flop 204 outputs scan data by shifting the scan chain data, as is known by those of skill in the art. The scan data is compared with expected data to test faults of the IC 100.

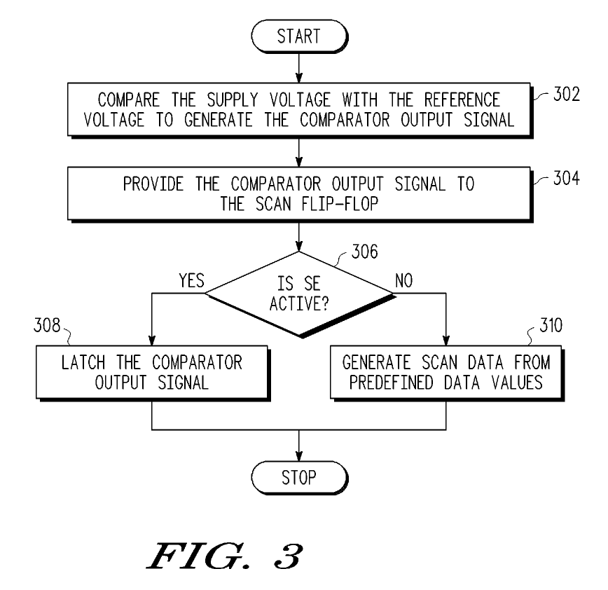

FIG. 3 is a flowchart depicting a method for detecting supply voltage degradation in the IC 100, in accordance with an embodiment of the present invention. At step 302, the supply voltage V_{DDACT} is compared with the reference voltage V_{REF} to generate the comparator output signal. At step 304, the comparator output signal is provided to the scan flip-flop 204. At step 306, the input SE is checked to determine whether SE is active or not. If SE is active, the comparator output signal is latched in the scan flip-flop 204, at step 308. However, if SE is not active, scan data is generated from the predefined data values (i.e., the scan chain), at step 310. Subsequently, the scan data is compared with expected data to check for faults in the IC 100.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

1. A scan cell for detecting supply voltage degradation in an integrated circuit, the integrated circuit including a power grid having a plurality of power rails that carry a supply voltage, the scan cell comprising:
a voltage comparator that compares the supply voltage carried by a selected one of the power rails from amongst the plurality of power rails with a reference voltage and generates a comparator output signal, wherein the reference voltage is based on a predetermined threshold voltage drop of the integrated circuit; and
a scan flip-flop coupled to the voltage comparator that receives the comparator output signal.

2. The scan cell of claim 1, wherein the scan cell latches the comparator output signal when a scan enable input to the scan flip-flop is active.

3. The scan cell of claim 1, wherein the scan cell is located at a point within the integrated circuit that corresponds to a location proximate to where the power rail experiences about maximum supply voltage degradation.

4. The scan cell of claim 1, wherein the reference voltage is carried from a voltage source to the voltage comparator by a stand-alone power line that is not connected to the power grid.

5. The scan cell of claim 1, wherein the reference voltage is the supply voltage less a maximum allowed voltage drop.

6. An integrated circuit including a plurality of scan cells each of which detects supply voltage degradation in the integrated circuit, and a power grid having a plurality of power rails that carry a supply voltage, each scan cell comprising:
a voltage comparator that compares the supply voltage carried by a selected one of the power rails from amongst the plurality of power rails with a reference voltage and generates a comparator output signal, wherein the reference voltage is based on a predetermined threshold voltage drop in the integrated circuit; and
a scan flip-flop coupled to the voltage comparator that receives the comparator output signal.

7. The scan cell of claim 6, wherein the scan cell latches the comparator output signal when a scan enable input to the scan flip-flop is active.

8. The scan cell of claim 6, wherein the reference voltage is carried from a voltage source to the voltage comparator by a stand-alone power line that is not connected to the power grid.

9. A method for detecting supply voltage degradation in an integrated circuit, the integrated circuit including a power grid having a plurality of power rails that carry a supply voltage, the method comprising:
comparing the supply voltage carried by at least one of the power rails from amongst the plurality of power rails with a reference voltage to generate a comparator output signal, wherein the reference voltage is based on a predetermined threshold voltage drop in the integrated circuit; and
providing the comparator output signal to a scannable latch circuit.

10. The method for detecting supply voltage degradation in an integrated circuit of claim 9, further comprising outputting a scan data from the scannable latch circuit.

11. The method for detecting supply voltage degradation in an integrated circuit of claim 10, wherein outputting the scan data comprises shifting predefined data values to obtain the shifted data when the scan enable input is not active.

12. The method for detecting supply voltage degradation in an integrated circuit of claim 10, further comprising comparing the scan data with expected data.

13. The method for detecting supply voltage degradation in an integrated circuit of claim 9, further comprising comparing the supply voltage carried by the power rail with the reference voltage at a point within the integrated circuit that corresponds to where the power rail experiences about maximum supply voltage degradation.

14. The method for detecting supply voltage degradation in an integrated circuit of claim 9, wherein the reference voltage is carried by a standalone power line that is not connected to the power grid.

15. The method for detecting supply voltage degradation in an integrated circuit of claim 9, wherein the reference voltage is the supply voltage less a maximum allowed voltage drop.
